(19) United States
(12) Patent Application Publication
(10) Pub. No.: US 2017/0141763 A1
(43) Pub. Date: May 18, 2017

(54) FREQUENCY DOUBLER HAVING OPTIMIZED HARMONIC SUPPRESSION CHARACTERISTICS

(71) Applicant: ELECTRONICS AND TELECOMMUNICATIONS RESEARCH INSTITUTE, Daejeon (KR)

(72) Inventors: Seong Mo MOON, Daejeon (KR); In Bok YOM, Daejeon (KR)

(73) Assignee: ELECTRONICS AND TELECOMMUNICATIONS RESEARCH INSTITUTE, Daejeon (KR)

(21) Appl. No.: 15/298,538

(22) Filed: Oct. 20, 2016

(30) Foreign Application Priority Data
Nov. 18, 2015 (KR) 10-2015-0161911

(51) Int. Cl. H03K 3/013; H03G 1/00; H03K 5/00

(52) U.S. Cl. CPC H03K 3/013; H03K 5/00006; H03G 1/0029

(57) ABSTRACT

Disclosed is a frequency doubler which controls a magnitude of a signal supplied to a virtual ground by adjusting a gain of one-side transistor among transistors receiving differential input signals when outputting a frequency multiplied LO signal through the virtual ground by amplifying the input differential signals by using a differential circuit structure to minimize undesired harmonics characteristics in a frequency doubled signal output by making the magnitudes of two differential signals be the same as each other.

### CROSS-REFERENCE TO RELATED APPLICATIONS

This application claims priority to and the benefit of Korean Patent Application No. 10-2015-0161911 filed in the Korean Intellectual Property Office on Nov. 18, 2015, the entire contents of which are incorporated herein by reference.

### TECHNICAL FIELD

The present invention relates to a frequency doubler, and particularly, to a frequency doubler which integrates a module that can generate a local oscillator (LO) signal which is frequency multiplied in a high frequency band by overcoming a frequency limit in a CMOS process and optimizing harmonic suppression characteristics by the CMOS process to be implemented on a chip.

### BACKGROUND ART

A frequency doubler is one of the core components for generating an LO signal in a high frequency band, but is not easily implemented due to various causes including a limit in process, and the like. A CMOS based frequency doubler reported in the related art may be implemented by not a differential scheme but a single scheme, but generally has a disadvantage in that harmonic suppression characteristics are bad. Further, it is reported that a differential scheme structure through an inverter type amplifier is used, but this also has a disadvantage in that the harmonic suppression characteristics become degraded due to an element layout and a parasitic error.

Besides, as a frequency doubler implemented by using a CMOS process, a differential scheme circuit structure can be used, which outputs a frequency multiplication signal by using a virtual ground. For example, by using the CMOS based differential circuit structure, signals frequency-multiplied with 2f0 and 4f0 can be output at an output port through the virtual ground with respect to a differential input signal having a frequency f0. A transistor receiving the differential input signal may be an NMOS transistor or adopt both the NMOS transistor and a PMOS transistor.

However, in the frequency multiplication using the CMOS based differential circuit structure in the related art, an undesired odd mode harmonics signal is generated on the virtual ground due to amplitude mismatch of the differential input signal, and as a result, an undesired harmonics signal is included in the frequency multiplied signal.

### SUMMARY OF THE INVENTION

The present invention has been made in an effort to provide a frequency doubler which controls a magnitude of a signal supplied to a virtual ground by adjusting a gain of one-side transistor among transistors receiving differential input signals when outputting a frequency multiplied LO signal through the virtual ground by amplifying the input differential signals by using a differential circuit structure to minimize undesired harmonics characteristics in a frequency doubled signal output by making the magnitudes of two differential signals be the same as each other.

The technical objects of the present invention are not limited to the aforementioned technical objects, and other technical objects, which are not mentioned above, will be apparently appreciated to a person having ordinary skill in the art from the following description.

An exemplary embodiment of the present invention provides a frequency doubler including: a differential circuit amplifying a differential AC signal input through a first input transistor and a second input transistor biased to first DC voltage and outputting a signal frequency-multiplied through a virtual ground; and a gain control circuit controlling an output gain of the frequency-multiplied signal by controlling current which flows on the first and second input transistors, wherein the gain control circuit includes a first control circuit for controlling current of the first input transistor by using one or more transistors and a second control circuit for controlling current of the second input transistor by using one or more other transistors and the first and second control circuits use bias by respective DC voltage.

One of the first and second control circuits may use the first DC voltage and the other one of the first and second control circuits may use second DC voltage having a different voltage value from the first DC voltage.

When the transistors are implemented by NMOS transistors, resistors may be connected between respective drain terminals of the first and second input transistors which are NMOS transistors and first power voltage.

When the transistors are implemented by the NMOS transistors, inductors may be connected between respective drain terminals of the first and second input transistors which are the NMOS transistors and the first power voltage.

When the transistors are implemented by PMOS transistors, the resistors may be connected between the respective drain terminals of the first and second input transistors which are the PMOS transistors and second power voltage.

When the transistors are implemented by the PMOS transistors, the inductors may be connected between the respective drain terminals of the first and second input transistors which are the PMOS transistors and the second power voltage.

The first control circuit may include a first transistor connected between the drain terminal of the first input transistor and predetermined voltage, the second control circuit may include a second transistor connected between the drain terminal of the second input transistor and the predetermined voltage, and the respective gate terminals of the first and second transistors may be biased by the respective DC voltage.

Alternatively, the first control circuit may include first and second transistors connected between the drain terminal of the first input transistor and the predetermined voltage in series and a third transistor connected between a first current source and the predetermined voltage and having a gate terminal and the drain terminal connected with each other, in which the gate terminal of the first transistor may be connected with the first DC voltage and the gate terminals of the second and third transistors may be connected with each other, and the second control circuit may include fourth and fifth transistors connected between the drain terminal of the second input transistor and the predetermined voltage in series and a sixth transistor connected between a second current source and the predetermined voltage and having the gate terminal and the drain terminal connected with each other, in which the gate terminal of the fourth transistor may be connected with the first DC voltage and the gate terminals of the fifth and sixth transistors may be connected with each other.

According to an exemplary embodiment of the present invention, a frequency doubler having optimized harmonics suppression characteristics applies a differential structure without using a single structure circuit scheme and adopts a method that adjusts a bias of an auxiliary transistor or one-side transistor of a differential amplifier in order to overcome an error of an input signal, which occurs in a differential structure to optimize harmonics suppression characteristics.

By overcoming a frequency limit of a CMOS process and optimizing the harmonics suppression characteristics, a frequency multiplied LO signal can be generated in a higher frequency band than an LO signal generated by a voltage control oscillator by two times or more.

Since the harmonics suppression characteristics which are a core standard in the frequency doubler can be optimized in a chip, an additional circuit is not required in implementing a module, and an LO module in a high frequency band is integrated by the CMOS process by overcoming a limit of the process to be implemented by on-chip.

The exemplary embodiments of the present invention are illustrative only, and various modifications, changes, substitutions, and additions may be made without departing from the technical spirit and scope of the appended claims by those skilled in the art, and it will be appreciated that the modifications and changes are included in the appended claims.

### BRIEF DESCRIPTION OF THE DRAWINGS

FIG. 1 is a circuit diagram of a frequency doubler according to a first exemplary embodiment of the present invention.

FIG. 2 is a circuit diagram of a frequency doubler according to a second exemplary embodiment of the present invention.

FIG. 3 is a circuit diagram of a frequency doubler according to a third exemplary embodiment of the present invention.

FIG. 4 is a circuit diagram of a frequency doubler according to a fourth exemplary embodiment of the present invention.

FIG. 5 is a circuit diagram of a frequency doubler according to a fifth exemplary embodiment of the present invention.

FIG. 6 illustrates an example of a differential signal input in the frequency doubler according to the present invention.

FIG. 7 illustrates a comparative example of output characteristics of frequency multiplied signals depending on the presence of a gain control circuit in the frequency doubler according to the present invention.

FIG. 8 illustrates an example of harmonics suppression characteristics of frequency multiplied signals in the frequency doubler according to the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, some exemplary embodiments of the present invention will be described in detail with reference to the exemplary drawings. When reference numerals refer to components of each drawing, it is noted that although the same components are illustrated in different drawings, the same components are designated by the same reference numerals as possible. In describing the exemplary embodiments of the present invention, when it is determined that the detailed description of the known components and functions related to the present invention may obscure understanding of the exemplary embodiments of the present invention, the detailed description thereof will be omitted.

Terms such as first, second, A, B, (a), (b), and the like may be used in describing the components of the exemplary embodiments of the present invention. The terms are only used to distinguish a component from another component, but nature or an order of the component is not limited by the terms. Further, if not contrarily defined, all terms used herein including technological or scientific terms have the same meanings as those generally understood by a person with ordinary skill in the art. Terms which are defined in a generally used dictionary should be interpreted to have the same meaning as the meaning in the context of the related art, and are not interpreted as an ideal meaning or excessively formal meanings unless clearly defined in the present application.

First, it will be described as an example that transistors M1, M2, M3, M4, M21, M22, M23, M25, M26, and M27 mentioned below are field effect transistor FETs having a metal-oxide-semiconductor (MOS) structure as illustrated in drawings. However, the present invention is not limited thereto and it will be, in advance, noted that the transistors M1, M2, M3, M4, M21, M22, M23, M25, M26, and M27 may be substituted with transistors having a different structure, which perform a similar function to the MOS-FET bipolar junction transistor (BJT), and the like as necessary. Further, all of the transistors M1, M2, M3, M4, M21, M22, M23, M25, M26, and M27 are preferably implemented to have the same channel width and length, but are not limited thereto and may be designed according to various design rules.

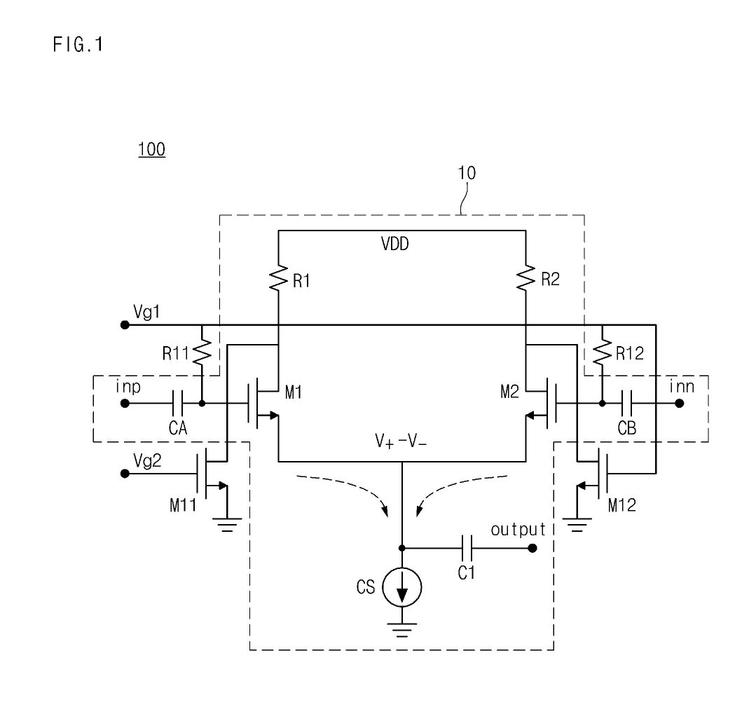

FIG. 1 is a circuit diagram of a frequency doubler 100 according to a first exemplary embodiment of the present invention.

Referring to FIG. 1, the frequency doubler 100 according to the first exemplary embodiment of the present invention includes a basic differential circuit 10 and residual circuits for optimizing harmonic suppression characteristics, that is, gain control circuits R11, R12, M11, and M12.

The differential circuit 10 is a circuit having a basic differential amplifier structure which amplifies a differential alternating current (AC) signal inp or inn input through a first input transistor M1 and a second input transistor M2 and outputs a signal (output) frequency-multiplied (e.g., doubled) through a virtual ground. A current source CS is connected between the virtual ground connected with source terminals of the first and second input transistors M1 and M2 and second power voltage (ground) and a frequency multiplied (e.g., doubled) amplification signal may be output through a capacitor C1 connected to the virtual ground. The differential AC signals inp and inn are input gate terminals of the first and second input transistors M1 and M2 through capacitors CA and CB, respectively.

However, only by the differential circuit 10, an undesired harmonics signal may be included in the frequency multiplied signal due to amplitude mismatch of the different AC signals inp and inn.

Therefore, in order to optimize the harmonics suppression characteristics according to the present invention, the respective gate terminals of the first and second input transistors M1 and M2 are biased to first direct current (DC) voltage Vg1 through a resistor R11/R12.

The frequency doubler 100 according to the first exemplary embodiment of the present invention includes auxiliary transistors M11 and M12 for optimizing the harmonics suppression characteristics and the respective transistors M11 and M12 control current which flows on the first and second input transistors M1 and M2 to control an output gain of the frequency multiplied signal output. As a result, a total gain difference of the first and second input transistors M1 and M2 is given to obtain the frequency multiplied signal output in which harmonics is minimized through the virtual ground with respect to the differential AC signals inp and inn having an amplitude difference.

In the frequency doubler 100 according to the first exemplary embodiment of the present invention in FIG. 1, an example in which transistors M1, M2, M11, and M12 are implemented by NOMOS (N-type MOS) transistors is shown and further, an example in which a load of the resistor R1/R2 is connected between respective drain terminals of the first and second input transistors M1 and M2 of the differential circuit 10 and first power voltage (e.g., VDD) is shown.

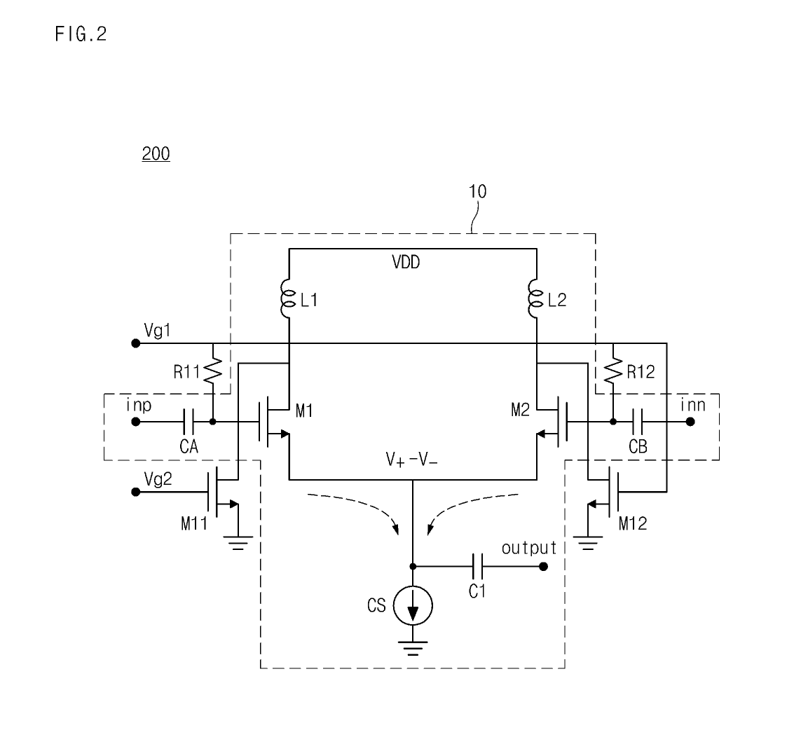

FIG. 2 is a circuit diagram of a frequency doubler 200 according to a second exemplary embodiment of the present invention.

FIG. 2 shows an example in which the frequency doubler 200 according to the second exemplary embodiment of the present invention in FIG. 2 mostly has a similar structure to the frequency doubler 100 according to the first exemplary embodiment of the present invention in FIG. 1, however, in order to increase a total gain, a load of an inductor L1/L2 is connected between respective drain terminals of the first and second input transistors M1 and M2 of the differential circuit 10 and the first power voltage (e.g., VDD).

An operation of the frequency doubler 200 according to the second exemplary embodiment of the present invention in FIG. 2 is similar to that of the frequency doubler 100 according to the first exemplary embodiment of the present invention in FIG. 1.

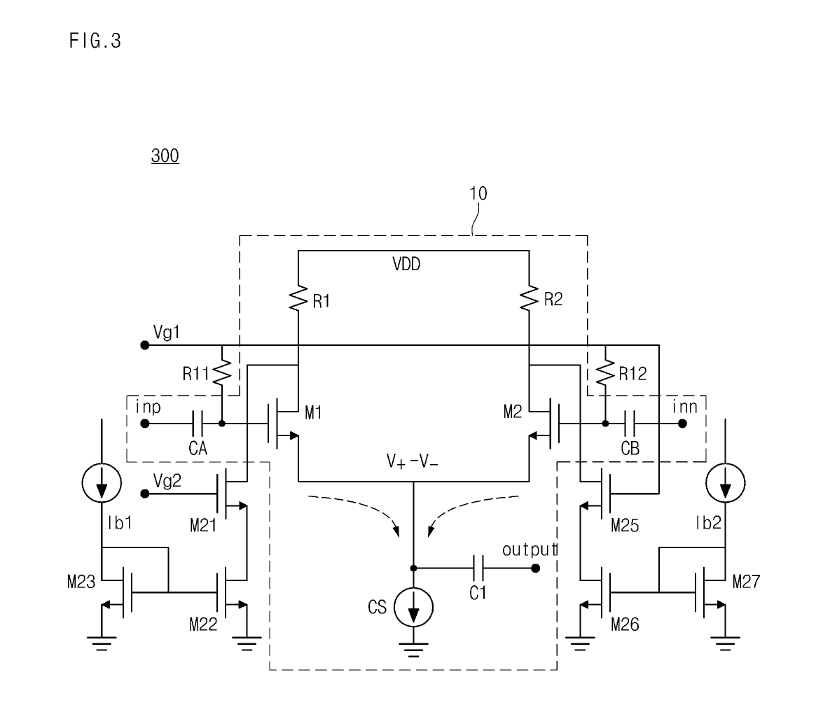

FIG. 3 is a circuit diagram of a frequency doubler 300 according to a third exemplary embodiment of the present invention.

The frequency doubler 300 according to the third exemplary embodiment of the present invention in FIG. 3 mostly has a similar structure to the frequency doubler 100 according to the first exemplary embodiment of the present invention in FIG. 1, however, FIG. 3 shows an example of using transistors M21, M22, M23/M25, M26, and M27 receiving the bias by a current source Ib1/Ib2 which serves as a current mirror instead of the auxiliary transistors M11 and M12 of FIG. 1. According to such a structure, the operation of the frequency doubler 300 according to the third exemplary embodiment of the present invention in FIG. 3 is also similar to that of the frequency doubler 100 according to the first exemplary embodiment of the present invention in FIG. 1. However, herein, since transconductance (gm) characteristics of the main input transistors M1 and M2 and the auxiliary transistors M11 and M12 may be enhanced, linearity of the signal supplied to the virtual ground is enhanced, thereby obtaining better harmonics suppression characteristics.

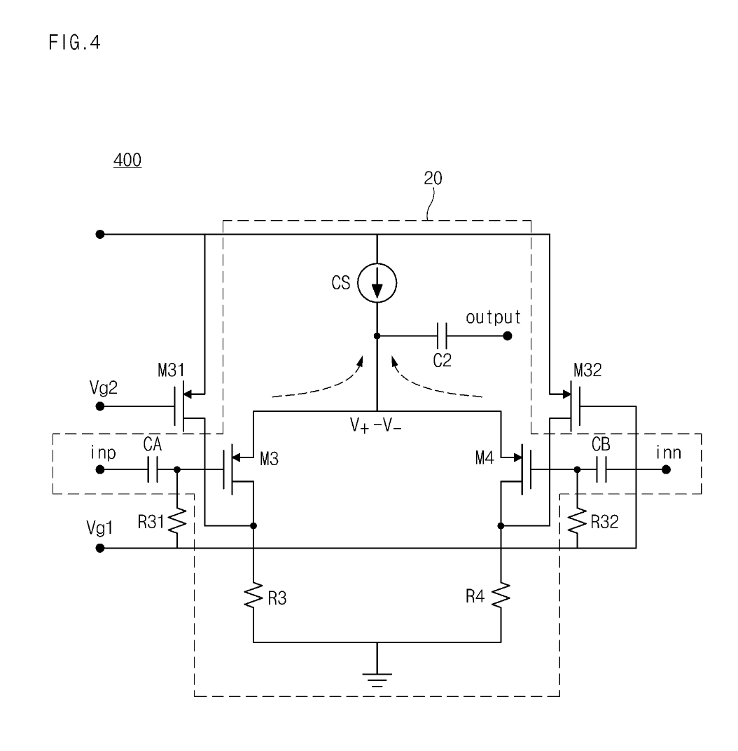

Meanwhile, as an example implemented by substituting the NMOS transistors M1, M2, M11, and M12 with PMOS (P-type MOS) transistors M3, M4, M31, and M32 in the frequency doubler 100 according to the first exemplary embodiment of the present invention, a frequency doubler 400 according to a fourth exemplary embodiment of the present invention in FIG. 4 is illustrated.

The operation of the frequency doubler 400 according to the fourth exemplary embodiment of the present invention in FIG. 4 is similar to that of the frequency doubler 100 according to the first exemplary embodiment of the present invention in FIG. 1. However, herein, auxiliary transistors M31 and M32 optimize the harmonics suppression characteristics and a load of a resistor R3/R4 is connected between the respective drain terminals of first and second input transistors M3 and M4 and second power voltage (e.g., the ground). The current source CS is connected between the virtual ground connected with source terminals of the first and second input transistors M3 and M4 and the first power voltage (e.g., VDD) and the frequency multiplied (e.g., doubled) amplification signal V₊-V₋ may be output through a capacitor C2 connected to the virtual ground.

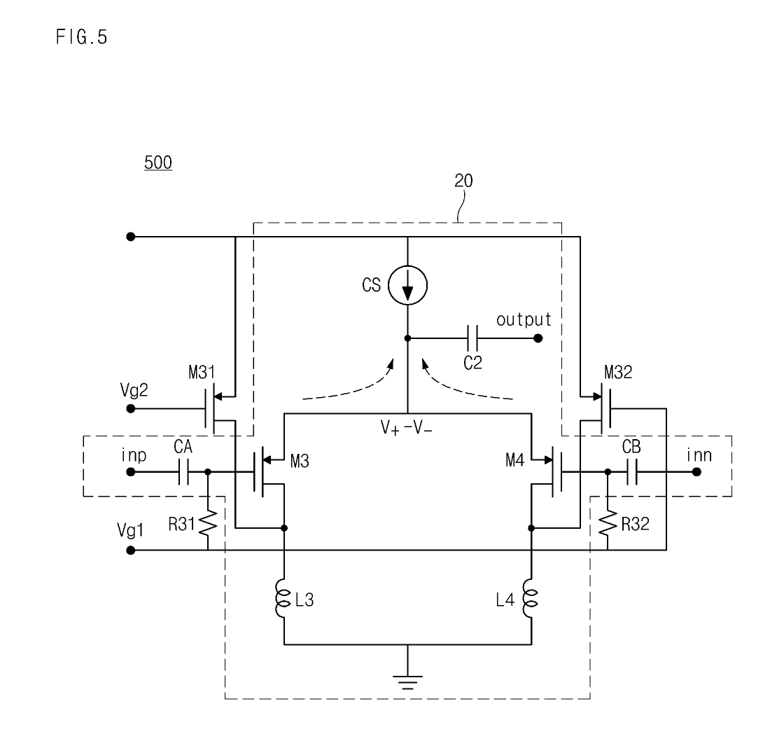

As an example implemented by substituting the NMOS transistors M1, M2, M11, and M12 with PMOS (P-type MOS) transistors M3, M4, M31, and M32 in the frequency doubler 200 according to the second exemplary embodiment of the present invention, a frequency doubler 500 according to a fifth exemplary embodiment of the present invention in FIG. 5 is illustrated.

The operation of the frequency doubler 500 according to the fifth exemplary embodiment of the present invention in FIG. 5 is similar to that of the frequency doubler 200 according to the second exemplary embodiment of the present invention in FIG. 2. However, herein, the auxiliary transistors M31 and M32 optimize the harmonics suppression characteristics and a load of an inductor L3/L4 is connected between the respective drain terminals of the first and second input transistors M3 and M4 and the second power voltage (e.g., the ground). The current source CS is connected between the virtual ground connected with source terminals of the first and second input transistors M3 and M4 and the first power voltage (e.g., VDD) and the frequency multiplied (e.g., doubled) amplification signal V₊-V₋ may be output through a capacitor C2 connected to the virtual ground.

The frequency doublers 100 to 500 according to the exemplary embodiments of the present invention control the current which flows on the first and second input transistors M1 and M2 by a gain control circuit including the auxiliary transistors (e.g., M11, M12, etc.,) to optimize the harmonics suppression characteristics by controlling the output gain of the frequency multiplied signal output.

That is, in FIGS. 1, 2, 4, and 5, the frequency doublers 100, 200, 400, and 500 include first control circuits M11 and M31 and second control circuits M12 and M32 including one or more transistors as the gain control circuit, respectively.

A first control circuit includes the transistor M11/M31 connected between the drain terminal of the first input transistor M1/M3 and predetermined voltage (e.g., the ground) and controls current of the first input transistor M1/M3. A second control circuit includes a transistor M12/M32 connected between the drain terminal of the second input transistor M2/M4 and the predetermined voltage (e.g., the ground) and controls current of the second input transistor M2/M4.

The transistor M11/M31 of the first control circuit and the transistor M12/M32 of the second control circuit receive the bias by respective DC voltage Vg1 and Vg2 through the respective gate terminals. In FIGS. 1, 2, 4, and 5, an example in which bias voltage Vg1 of the first input transistor M1/M3 and the second input transistor M2/M4 is biased even to the transistor M12/M32 of the second control circuit and the transistor M11/M31 of the first control circuit is biased to the bias voltage Vg2 having a different voltage value is illustrated. However, the present invention is not limited thereto and the transistor M11/M31 of the first control circuit and the transistor M12/M32 of the second control circuit may be biased to different DC voltage having the different voltage values and as one example, one of the bias voltage may be the same as the bias voltage Vg1 of the first input transistor M1/M3 and the second input transistor M2/M4.

Meanwhile, as illustrated in FIG. 3, the frequency doubler 300 using the transistors M21, M22, M23/M25, M26, and M27 receiving the bias by the current source Ib1/Ib2 serving as the current mirror instead of the auxiliary transistors M11 and M12 as the gain control circuit includes the first control circuits M21, M22, and M23 and the second control circuits M25, M26, and M27 each including one or more transistors. The first control circuits M21, M22, and M23 control the current which flows on the first input transistor M1 and the second control circuits M25, M26, and M27 control the current which flows on the second input transistor M2 to control the output gain of the frequency multiplied signal output, thereby optimizing the harmonics suppression characteristics.

Herein, in the first control circuit, the first transistor M21 and the second transistor M22 are, in series, connected between the drain terminal of the first input transistor M1 and the predetermined voltage (e.g., the ground). A third transistor M23 is connected between a first current source Ib1 and the predetermined voltage (e.g., the ground) and the gate terminal and the drain terminal of the third transistor M23 are connected with each other. The gate terminal of the first transistor M21 is connected with first DC voltage Vg1 and the gate terminals of the second and third transistors M22 and M23 are connected with each other.

In the second control circuit, a fourth transistor M25 and a fifth transistor M26 are, in series, connected between the drain terminal of the second input transistor M2 and the predetermined voltage (e.g., the ground). A sixth transistor M27 is connected between a second current source Ib2 and the predetermined voltage (e.g., the ground) and the gate terminal and the drain terminal of the sixth transistor M27 are connected with each other. The gate terminal of the fourth transistor M25 is connected with first DC voltage Vg1 and the gate terminals of the fifth and sixth transistors M26 and M27 are connected with each other.

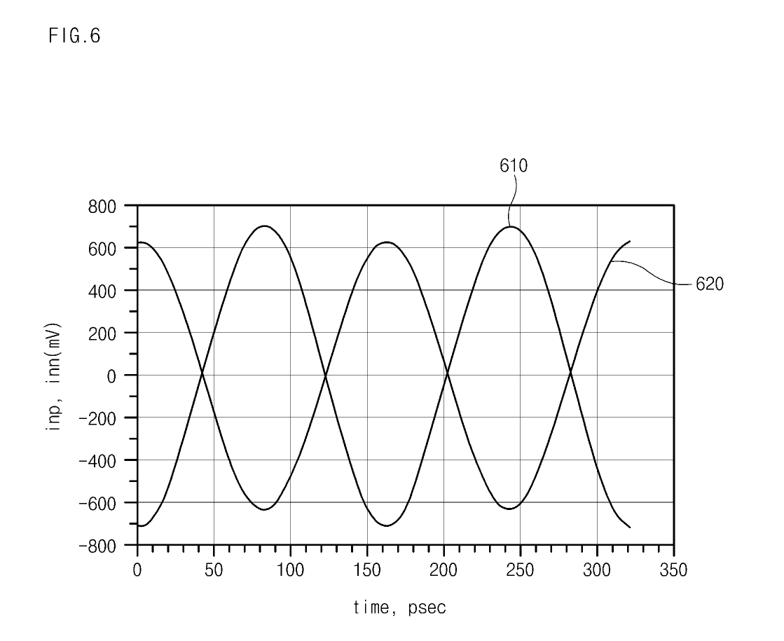

FIG. 6 illustrates an example of differential signals input in the frequency doublers 100 to 500 according to the present invention.

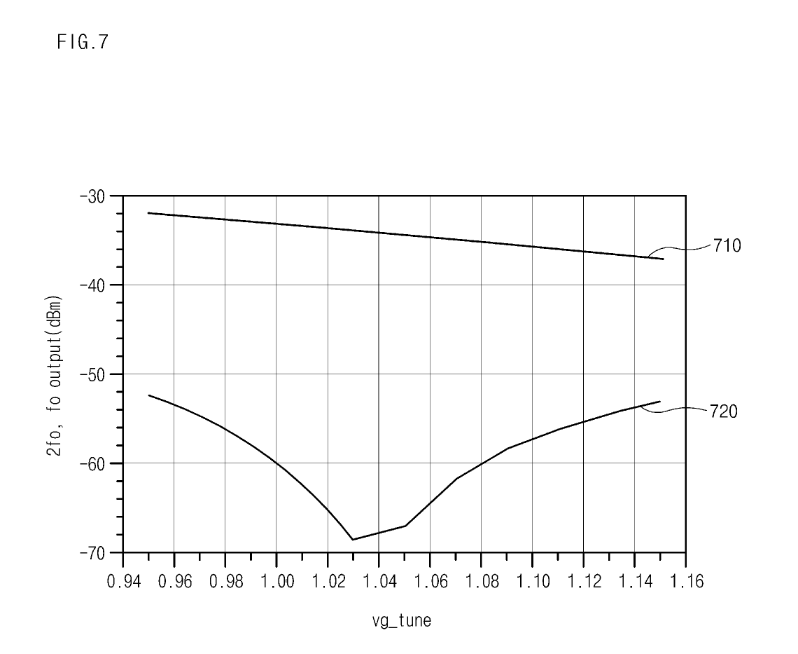

FIG. 7 illustrates a comparative example of output characteristics of frequency multiplied signals depending on the presence of a gain control circuit in the frequency doublers 100 to 500 according to the present invention.

As illustrated in FIG. 6, when input differential signals 610 and 620 having a frequency f0 of approximately 6.5 GHz, which has an amplitude size difference of 0.2 Vpp are applied to the first input transistor M1/M3 and the second input transistor M2/M4, in the case where the gain control circuit of the present invention is present as illustrated in FIG. 7 (720), a simulation result having low harmonics characteristics of the signal frequency multiplied with 2f0 compared to a case in which there is no gain control circuit (710) is verified.

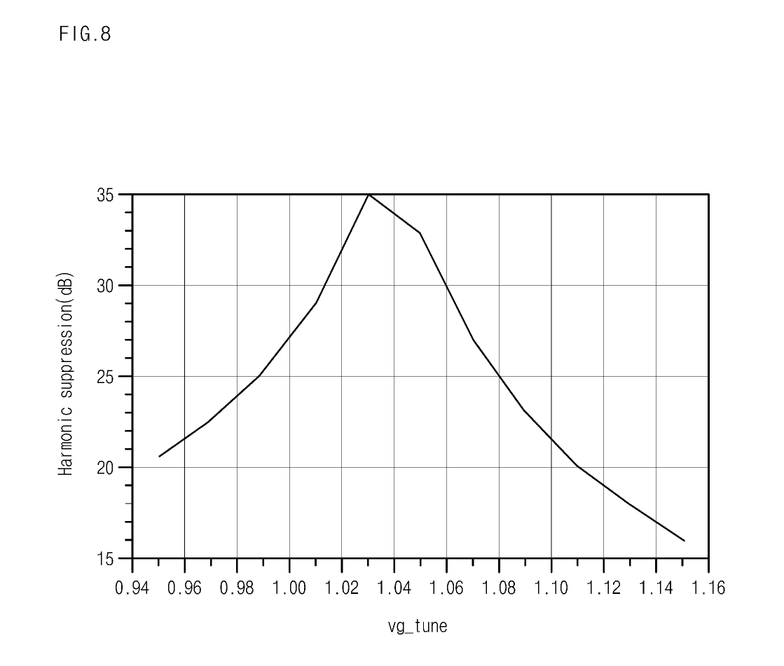

That is, when the first DC voltage Vg1 biased to the transistor M11/M31 of the first control circuit is 1.2 V, it may be verified that the harmonics suppression characteristics are optimized when the second DC voltage Vg2 biased to the transistor M12/M32 of the second control circuit is 1.03 V as illustrated in FIG. 8.

As described above, the frequency doublers 100 to 500 having optimized harmonics suppression characteristics according to the present invention adopt the differential structure without using a single structure circuit scheme and adopt a method that adjusts a bias of an auxiliary transistor or one-side transistor of a differential amplifier in order to overcome an error of an input signal, which occurs in a differential structure to optimize harmonics suppression characteristics. Further, by overcoming a frequency limit of a CMOS process and optimizing the harmonics suppression characteristics, a frequency multiplied LO signal can be generated in a higher frequency band than an LO signal generated by a voltage control oscillator by two times or more and in addition, since the harmonics suppression characteristics which are a core standard in the frequency doubler can be optimized in a chip, an additional circuit is not required in implementing a module and an LO module in a high frequency band is integrated by the CMOS process by overcoming a limit of the process to be implemented by on-chip.

The above description just illustrates the technical spirit of the present invention and various changes and modifications can be made by those skilled in the art to which the present invention pertains without departing from an essential characteristic of the present invention.

Therefore, the exemplary embodiments disclosed in the present invention are used to not limit but describe the technical spirit of the present invention and the scope of the technical spirit of the present invention is not limited by the exemplary embodiments. The scope of the present invention should be interpreted by the appended claims and it should be understood that all technical spirit in the equivalent range thereto is intended to be embraced by the scope of the present invention.

What is claimed is:

1. A frequency doubler comprising:
a differential circuit amplifying a differential AC signal input through a first input transistor and a second input transistor biased to first DC voltage and outputting a signal frequency-multiplied through a virtual ground; and
a gain control circuit controlling an output gain of the frequency-multiplied signal by controlling current which flows on the first and second input transistors,
wherein the gain control circuit includes a first control circuit for controlling current of the first input transistor by using one or more transistors and a second control circuit for controlling current of the second input transistor by using one or more other transistors and the first and second control circuits use bias by respective DC voltage.

2. The frequency doubler of claim 1, wherein one of the first and second control circuits uses the first DC voltage and the other one of the first and second control circuits uses second DC voltage having a different voltage value from the first DC voltage.

3. The frequency doubler of claim 1, wherein resistors are connected between respective drain terminals of the first and second input transistors which are NMOS transistors and first power voltage.

4. The frequency doubler of claim 1, wherein inductors are connected between the respective drain terminals of the first and second input transistors which are NMOS transistors and the first power voltage.

5. The frequency doubler of claim 1, wherein the resistors are connected between the respective drain terminals of the first and second input transistors which are PMOS transistors and second power voltage.

6. The frequency doubler of claim 1, wherein the inductors are connected between the respective drain terminals of the first and second input transistors which are the PMOS transistors and the second power voltage.

7. The frequency doubler of claim 1, wherein the first control circuit includes a first transistor connected between the drain terminal of the first input transistor and predetermined voltage,
the second control circuit includes a second transistor connected between the drain terminal of the second input transistor and the predetermined voltage, and
respective gate terminals of the first and second transistors are biased by the respective DC voltage.

8. The frequency doubler of claim 1, wherein the first control circuit includes first and second transistors connected between the drain terminal of the first input transistor and the predetermined voltage in series and a third transistor connected between a first current source and the predetermined voltage and having the gate terminal and the drain terminal connected with each other, in which the gate terminal of the first transistor is connected with the first DC voltage and the gate terminals of the second and third transistors are connected with each other, and
the second control circuit includes fourth and fifth transistors connected between the drain terminal of the second input transistor and the predetermined voltage in series and a sixth transistor connected between a second current source and the predetermined voltage and having the gate terminal and the drain terminal connected with each other, in which the gate terminal of the fourth transistor is connected with the first DC voltage and the gate terminals of the fifth and sixth transistors are connected with each other.
